(19) United States
(12) Patent Application Publication
(10) Pub. No.: US 2025/0229491 A1
(43) Pub. Date: Jul. 17, 2025

(54) A PROCESS FOR THE PREPARATION OF A MULTI-PHASE COMPOSITE 3D OBJECT

(71) Applicant: BASF SE, Ludwigshafen am Rhein (DE)

(72) Inventors: Fan ZHANG, Shanghai (CN); Zhi Zhong CAI, Shanghai (CN); Jie LU, Shanghai (CN); Peter MUELLER, Ludwigshafen am Rhein (DE); Florian NIEDERHOEFER, Dautphetal (DE)

(21) Appl. No.: 18/691,058

(22) PCT Filed: Aug. 31, 2022
(86) PCT No.: PCT/EP2022/074213

§ 371 Date: Mar. 12, 2024

(30) Foreign Application Priority Data
Sep. 13, 2021 (WO) PCT/CN2021/118002

(51) Int. Cl. B29C 64/336; B29C 64/112; B29C 64/209; B29C 64/386; B33Y 10/00; B33Y 50/00; B33Y 70/00

(52) U.S. Cl. CPC B29C 64/336; B29C 64/112; B29C 64/209; B29C 64/386; B29K 2995/0077; B33Y 10/00; B33Y 50/00; B33Y 70/00

(57) ABSTRACT

A process for the preparation of a multi-phase composite 3D object comprising the core and shell, which comprises: (A) Generating data of the core and shell of a 3D model of the 3D object; (B) Building the core of said 3D model from at least one first composition and building the shell of said 3D model from at least one second composition according to the data generated, wherein the core is built by dispensing the at least one first composition from a first dispenser, and (C) Solidifying the at least one first composition and the at least one second composition to obtain the multi-phase composite 3D object, wherein the solidified material of the at least one first composition and the solidified material of the at least one second composition have different properties.

### TECHNOLOGY FIELD

The present invention belongs to the technical field of chemical materials for three-dimensional (hereinafter referred to as “3D”) printing, and in particular relates to a process for the preparation of a multi-phase composite 3D object and a multi-phase composite 3D object obtainable by the same.

### BACKGROUND

3D-printing technologies using curable polymer, e.g., stereolithography (SLA), digital light processing (DLP) or photopolymer jetting (PPJ), have been used in many applications, such as rapid prototyping and rapid manufacturing processes of hearing aids or dental parts. However, there is a strong need to develop a simple process for preparing 3D object with improved properties.

### SUMMARY OF THE INVENTION

It is an object of the invention to provide a process for the preparation of a multi-phase composite 3D object comprising the core and shell.

Another object of the present invention is to provide a multi-phase composite 3D object obtainable by the process according to the present invention.

It has been surprisingly found that the above objects can be achieved by following embodiments:
1. A process for the preparation of a multi-phase composite 3D object comprising the core and shell, which comprises:
   (A) Generating data of the core and shell of a 3D model of the 3D object;
   (B) Building the core of said 3D model from at least one first composition and building the shell of said 3D model from at least one second composition according to the data generated, wherein the core is built by dispensing the at least one first composition from a first dispenser; and
   (C) Solidifying the at least one first composition and the at least one second composition to obtain the multi-phase composite 3D object,
   wherein the solidified material of the at least one first composition and the solidified material of the at least one second composition have different properties.
2. The process according to item 1, wherein the data of the core and shell of a 3D model of the 3D object is generated from a computer aided design (CAD) system in step (A).
3. The process according to item 1 or 2, wherein the thickness of the shell is at least 1 μm, preferably at least 14 μm, more preferably at least 30 μm.
4. The process according to any of items 1 to 3, wherein the thickness of the shell is in the range from 1 to 3000 μm, preferably from 14 to 1500 μm, more preferably from 30 to 1500 μm or from 40 to 500 μm.
5. The process according to any of items 1 to 4, wherein the thickness of the shell is even or uneven.
6. The process according to any of items 1 to 5, wherein the core comprises one or more layers.
7. The process according to any of items 1 to 6, wherein the solidified material of the at least one first composition and the solidified material of the at least one second composition are different in at least one of following properties: mechanical properties, thermal properties, electronic properties, optical properties and chemical-resistance properties.
8. The process according to item 7, wherein the mechanical properties comprise at least one of following properties: Young's modulus, tensile strength, elongation at break, tensile toughness, and impact strength.
9. The process according to any of items 1 to 8, wherein the at least one first composition and the at least one second composition meet at least one of following conditions:
(i) the unnotched impact strength of the solidified material of the at least one second composition is at least 150%, preferably at least 200% of the unnotched impact strength of the solidified material of the at least one first composition;
(ii) the notched impact strength of the solidified material of the at least one second composition is 150%, preferably at least 200% of the notched impact strength of the solidified material of the at least one first composition;
(iii) the elongation at break of the solidified material of the at least one second composition is at least 150%, preferably at least 200% of the elongation at break of the solidified material of the at least one first composition.
10. The process according to any of items 1 to 9, wherein the at least one first composition and the at least one second composition meet at least one of following conditions:
(iv) the Young's modulus of the solidified material of the at least one first composition is at least 120%, preferably at least 150% of the Young's modulus of the solidified material of the at least one second composition;
(v) the tensile strength of the solidified material of the at least one first composition is at least 120%, preferably at least 150% of the tensile strength of the solidified material of the at least one second composition.
11. The process according to any of items 1 to 10, wherein, the shell is built by dispensing the at least one second composition from a second dispenser, by dip coating the at least one second composition and/or by spin coating the at least one second composition.
12. The process according to any of items 1 to 11, wherein the dispensing comprises dispensing via ink jet nozzles, dispensing via extrusion or dispensing via spray coating.
13. The process according to any of items 1 to 12, wherein the core is built by dispensing the at least one first composition from a first dispenser via ink jet nozzles, and the shell is built by dispensing the at least one second composition from a second dispenser via ink jet nozzles.
14. The process according to any of items 1 to 13, wherein the core and/or shell further comprises 2D-3D structure which exhibits isotropic properties, anisotropic properties, and a combination thereof.
15. The process according to item 14, wherein the 2D-3D structure is selected from honeycomb, auxetic, stack and chessboard structure.
16. The process according to any of items 1 to 15, wherein at least one of compositions comprises a curable component.
17. The process according to any of items 1 to 16, wherein the solidifying in step (C) is carried out by heat, solvent evaporation, radiation such as UV radiation, electron beam and microwave, or any combination thereof.
18. A multi-phase composite 3D object obtainable by the process according to any of items 1 to 17.

According to the process of the present invention, 3D objects with improved properties, such as mechanical properties, especially impact strength and elongation at break can be obtained in a simple way and modulus and tensile strength still remain high. The process can also easily adjust the properties of 3D objects.

### DESCRIPTION OF THE DRAWING

FIG. 1 is a schematic illustration of 3D object comprising the core and shell—Cross section view.

FIG. 2 is a schematic illustration of 3D object comprising the core and shell—3D view.

FIG. 3 is a schematic illustration of 3D object comprising the core and shell—3D view, wherein FIG. 3(a) shows core further comprises 2D-3D structures, FIG. 3(b) shows shell further comprises 2D-3D structures, and FIG. 3 (c) shows both core and shell further comprise 2D-3D structures.

FIG. 4 is a schematic illustration of 3D printing system.

FIG. 5 shows effects of shell thickness on Izod unnotched impact strength.

FIG. 6 is a schematic illustration of complex structures printed by building core of the specimen using different materials.

FIG. 7 is a schematic illustration of complex structures built by using composition A and composition B.

FIG. 8 is a schematic illustration of shell and core further comprising complex structures printed by using different materials.

### EMBODIMENT OF THE INVENTION

The undefined article “a”, “an”, “the” means one or more of the species designated by the term following said article.

In the context of the present disclosure, any specific values mentioned for a feature (comprising the specific values mentioned in a range as the end point) can be recombined to form a new range.

One aspect of the present invention is directed to a process for the preparation of a multi-phase composite 3D object comprising the core and shell, which comprises:
(A) Generating data of the core and shell of a 3D model of the 3D object;
(B) Building the core of said 3D model from at least one first composition and building the shell of said 3D model from at least one second composition according to the data generated, wherein the core is built by dispensing the at least one first composition from a first dispenser; and
(C) Solidifying the at least one first composition and the at least one second composition to obtain the multi-phase composite 3D object,

wherein the solidified material of the at least one first composition and the solidified material of the at least one second composition have different properties.

In an embodiment, the data of the core and shell of a 3D model of the 3D object is generated from a computer aided design (CAD) system in step (A).

According to the present invention, the shell is the layer with its surface being connected to exterior and the core is the remaining part.

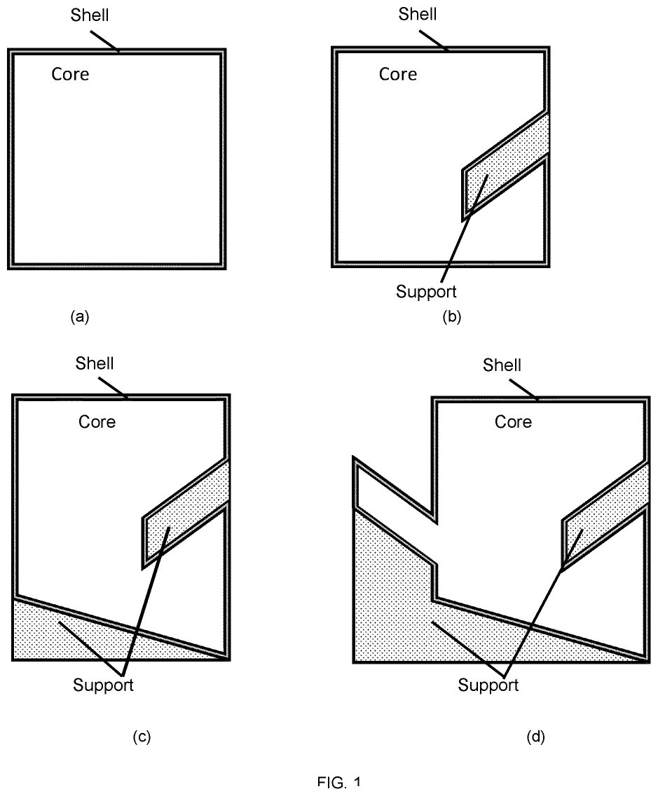

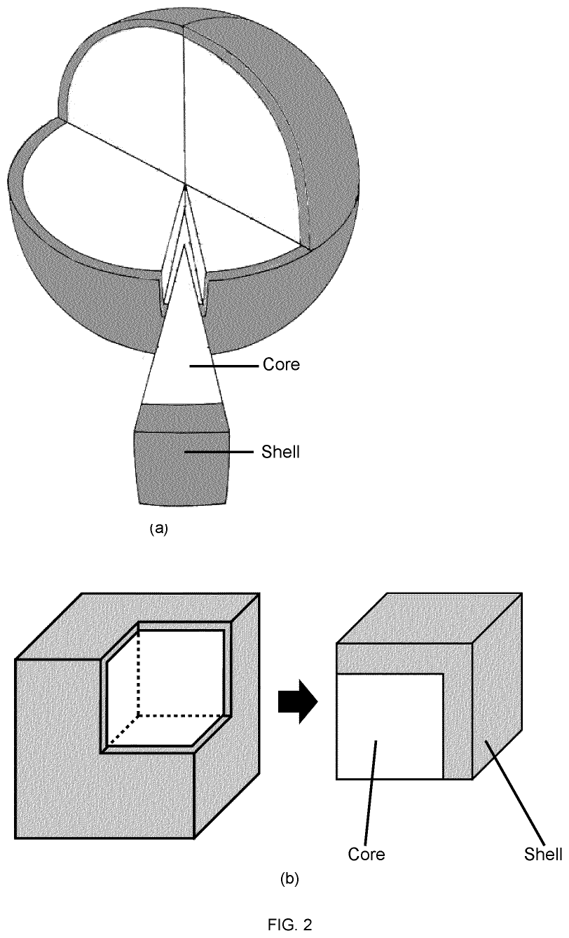

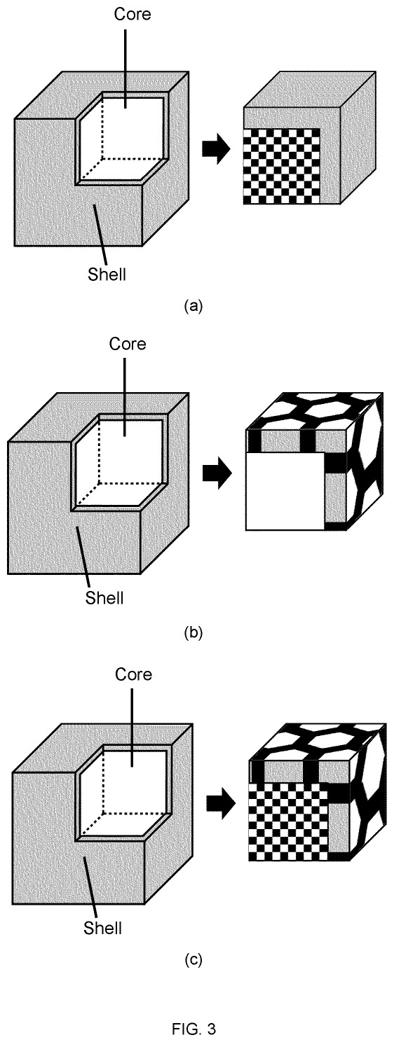

FIGS. 1, 2 and 3 show examples of 3D objects comprising the core and shell.

The thickness of the shell can be at least 1 μm, preferably at least 14 μm, more preferably at least 30 μm, for example 40 μm, 50 μm, 60 μm, 70 μm, 80 μm, 90 μm, 100 μm, 120 μm, 150 μm, 200 μm, 250 μm, 300 μm, 500 μm, 800 μm, 1000 μm, 1500 μm, 2000 μm, 2500 μm or 3000 μm.

In an embodiment, the thickness of the shell can be in the range from 1 to 3000 μm or 10 to 2000 μm, preferably from 14 to 3000 μm, 14 to 2000 μm, 14 to 1500 μm, more preferably from 30 to 3000 μm, 30 to 2000 μm, 30 to 1500 μm, 40 to 3000 μm, 40 to 2000 μm, 40 to 1500 μm, 50 to 3000 μm, 50 to 2000 μm, 50 to 1500 μm, 60 to 3000 μm, 60 to 2000 μm, 60 to 1500 μm, 70 to 1500 μm, 40 to 1000 or from 40 to 500 μm.

In an embodiment, the thickness of the shell can be even or uneven. In an embodiment, the thickness of the shell is even along the primary stress direction of the 3D molding. In the scenario that the thickness of the shell is uneven, a person skilled in the art could understand that the thickness of the shell (value or range) as mentioned above means the average thickness of the shell.

In an embodiment, the core can comprise one or more layers (inner layers), for example one, or two or three or more inner layers. In an embodiment, if there are two or more inner layers, the adjacent inner layers have different properties. In an embodiment, the adjacent inner layers have different properties and the non-adjacent inner layers have the same properties. In an embodiment, the adjacent inner layers have different properties and the non-adjacent inner layers also have the different properties. In an embodiment, the properties of all these inner layers are different. Details of these properties can refer to the description below for the properties of the solidified material of the at least one first composition and the solidified material of the at least one second composition.

The thickness of each inner layer can be at least 1 μm, at least 14 μm, at least 30 μm, at least 70 μm, at least 200 μm, at least 500 μm, at least 1000 μm, at least 1500 μm, at least 2000 μm, at least 2500 μm or at least 3000 μm. The thickness of different inner layers can be the same or different.

In an embodiment, the solidified material of the at least one first composition and the solidified material of the at least one second composition are different in at least one of following properties: mechanical properties, thermal properties, electronic properties, optical properties and chemical-resistance properties.

The mechanical properties can comprise Young's modulus, tensile strength, elongation at break, tensile toughness, and impact strength. Thermal properties can comprise Heat Deflection Temperature, coefficient of thermal expansion, etc. The electrical properties can comprise dielectric constant, conductivity, etc. Chemical-resistance properties comprises the resistance to acid, base, oxygen, solvent etc.

In a preferred embodiment, the solidified material of the at least one first composition and the solidified material of the at least one second composition are different in at least one (for example at least two, at least three, at least four or all) of following properties: Young's modulus, tensile strength, elongation at break, tensile toughness, and impact strength.

In a preferred embodiment, the at least one first composition and the at least one second composition meet at least one of following conditions:
(i) the unnotched impact strength of the solidified material of the at least one second composition is at least 150%, preferably at least 200% of the unnotched impact strength of the solidified material of the at least one first composition;
(ii) the notched impact strength of the solidified material of the at least one second composition is 150%, preferably at least 200% of the notched impact strength of the solidified material of the at least one first composition;
(iii) the elongation at break of the solidified material of the at least one second composition is at least 150%, preferably at least 200% of the elongation at break of the solidified material of the at least one first composition.

In condition (i), the unnotched impact strength of the solidified material of the at least one second composition can be at least 150%, at least 200% (for example 250%, 300%, 350%, 400%, 450%, 500%, 550% or 600%), preferably at least 220% or at least 250% of the unnotched impact strength of the solidified material of the at least one first composition. Preferably, the unnotched impact strength of the solidified material of the at least one second composition can be from 150% to 600%, or from 200% to 500%, or from 250 to 450%, or from 250 to 400%, or from 250 to 350% of the unnotched impact strength of the solidified material of the at least one first composition.

According to the present invention, if the unnotched impact strength of the solidified material of the at least one first composition is x; and the unnotched impact strength of the solidified material of the at least one second composition is y, then the unnotched impact strength of the solidified material of the at least one second composition is (y/x)×100% of the unnotched impact strength of the solidified material of the at least one first composition. Other parameters can be calculated accordingly.

If there are two or more first composition, the unnotched impact strength of the solidified material of two or more first composition means their weight average value. For example, there are two first compositions, i.e., composition 10 and composition 11, wherein composition 10 is 30 wt % and composition 11 is 70 wt % and their unnotched impact strengths are m and n, respectively, the weight average unnotched impact strength can be calculated as 30%×m+70%×n. The same applies for the two or more second compositions and other parameters.

In condition (ii), the notched impact strength of the solidified material of the at least one second composition can be at least 150%, at least 200% (for example 250%, 300%, 350%, 400%, 450%, 500%, 600%, 700%, 800%), preferably at least 220%, at least 250%, or at least 300% of the notched impact strength of the solidified material of the at least one first composition.

Preferably, the notched impact strength of the solidified material of the at least one second composition can be from 150% to 800%, or from 200% to 700%, from 250% to 600%, or from 300% to 500% of the notched impact strength of the solidified material of the at least one first composition.

In condition (iii), the elongation at break of the solidified material of the at least one second composition is at least 150% (for example 200%, 250%, 300%, 500%, 600%, 800%, 1000%, 1200% or 1500%), preferably at least 200% or at least 500% of the elongation at break of the solidified material of the at least one first composition. Preferably, the elongation at break of the solidified material of the at least one second composition can be from 150% to 1500%, 200% to 1400%, or 300% to 1200%, or 500% to 1200%, or 600% to 1200%.

In an embodiment, the at least one first composition and the at least one second composition meet condition (i), or condition (ii), or condition (iii), or conditions (i) and (ii), or conditions (i) and (iii), or conditions (ii) and (iii), or conditions (i), (ii) and (iii).

In a preferred embodiment, the at least one first composition and the at least one second composition meet at least one (for example one or two) of following conditions:
(iv) the Young's modulus of the solidified material of the at least one first composition is at least 120%, preferably at least 150% of the Young's modulus of the solidified material of the at least one second composition;
(v) the tensile strength of the solidified material of the at least one first composition is at least 120%, preferably at least 150% of the tensile strength of the solidified material of the at least one second composition.

In this disclosure, the Young's modulus, tensile strength and the elongation at break can be tested according to ASTM D638.

In this disclosure, the Izod notched impact strength can be tested according to ASTM-D256-10 at room temperature.

In this disclosure, the Izod unnotched impact strength can be tested according to ASTM-D4812-11.

In condition (iv), the Young's modulus of the solidified material of the at least one first composition is at least 120% (for example 130%, 140%, 150%, 160%, 180%, 200%, 250%, 300%, 350% or 400%), preferably at least 150% of the Young's modulus of the solidified material of the at least one second composition. Preferably, the Young's modulus of the solidified material of the at least one first composition is from 120% to 400%, or from 130% to 350%, or from 140% to 300%, or from 150% to 250% of the Young's modulus of the solidified material of the at least one second composition.

In condition (v), the tensile strength of the solidified material of the at least one first composition is at least 120% (for example 130%, 140%, 150%, 160%, 180%, 200%, 250%, 300%, 350% or 400%), preferably at least 150% of the tensile strength of the solidified material of the at least one second composition. Preferably, the tensile strength of the solidified material of the at least one first composition is from 120% to 400%, or from 130% to 350%, or from 140% to 300%, or from 150% to 250% of the tensile strength of the solidified material of the at least one second composition.

In an embodiment, the at least one first composition and the at least one second composition meet condition (iv), or condition (v), or conditions (iv) and (v).

In an embodiment, the at least one first composition and the at least one second composition meet at least one (for example at least one, two, three, four or all) of following conditions: (i), (ii), (iii), (iv) and (v). For example, the at least one first composition and the at least one second composition meet conditions (i) and (iv), or conditions (i) and (v), or conditions (ii) and (iv), or conditions (ii) and (v), or conditions (i), (ii), (iii) and (iv), or conditions (i), (ii), (iii) and (v), or conditions (i), (ii), (iii), (iv) and (v).

### The Component of the First and Second Composition

### Curable Component

According to the present invention, at least one of compositions comprises at least one curable component.

In an embodiment, the first composition comprises at least one curable component. In an embodiment, the second composition comprises at least one curable component. In an embodiment, both the first and the second composition comprises at least one curable component.

Said curable component is curable by heat, solvent evaporation, radiation such as UV radiation, electron beam and microwave, or any combination thereof, preferably by UV radiation or heat or combination thereof.

Preferably, the curable component suitable for the present invention may contain at least one radiation-curable functional group.

In an embodiment of the present invention, curable component of the present invention comprises a monomer and/or oligomer containing at least one radiation-curable functional group.

Preferably, the radiation-curable functional group is selected from the group consisting of an ethylenically unsaturated functional group, an epoxy group, or the mixture thereof.

Preferably, the number of the radiation-curable functional group in curable component is in the range from 1 to 10, preferably from 1 to 8, such as from 1 to 6, for example 1, 2, 3, 4, 5 or 6, per molecule of curable component.

As curable component containing at least one epoxy group, non-limiting examples may include epoxidized olefins, aromatic glycidyl ethers, aliphatic glycidyl ethers, or the combination thereof, preferably aromatic or aliphatic glycidyl ethers.

Examples of possible epoxidized olefins include epoxidized C₂-C₁₀-olefins, such as ethylene oxide, propylene oxide, iso-butylene oxide, 1-butene oxide, 2-butene oxide, vinyloxirane, styrene oxide or epichlorohydrin, preference being given to ethylene oxide, propylene oxide, isobutylene oxide, vinyloxirane, styrene oxide or epichlorohydrin, particular preference to ethylene oxide, propylene oxide or epichlorohydrin, and very particular preference to ethylene oxide and epichlorohydrin.

Aromatic glycidyl ethers are, for example, bisphenol A diglycidyl ether, bisphenol F diglycidyl ether, bisphenol B diglycidyl ether, bisphenol S diglycidyl ether, hydroquinone diglycidyl ether, alkylation products of phenol/dicyclopentadiene, e.g., 2,5-bis[(2,3-epoxypropoxy)phenyl]octahydro-4,7-methano-5H-indene (CAS No. [13446-85-0]), tris[4-(2,3-epoxypropoxy)phenyl]methane isomers (CAS No. [66072-39-7]), phenol-based epoxy novolaks (CAS No. [9003-35-4]), and cresol-based epoxy novolaks (CAS No. [37382-79-9]).

Examples of aliphatic glycidyl ethers include 1,4-butanediol diglycidyl ether, 1,6-hexanediol diglycidyl ether, trimethylolpropane triglycidyl ether, pentaerythritol tetraglycidyl ether, 1,1,2,2-tetrakis[4-(2,3-epoxypropoxy)phenyl]ethane (CAS No. [27043-37-4]), diglycidyl ether of polypropylene glycol (α,ω-bis(2,3-epoxypropoxy)poly(oxypropylene), CAS No. [16096-30-3]) and of hydrogenated bisphenol A (2,2-bis[4-(2,3-epoxypropoxy)cyclohexyl]propane, CAS No. [13410-58-7]).

More preferably, the curable component contains at least one ethylenically unsaturated functional group.

In an embodiment of the invention, the ethylenically unsaturated functional group contains a carbon-carbon unsaturated bond, such as those found in the following functional groups: allyl, vinyl, (meth)acrylate, (meth)acryloxy, (meth)acrylamido, acetylenyl, maleimido, (meth)acryloyl and the like; preferably, the ethylenically unsaturated functional group contains a carbon-carbon unsaturated double bond; more preferably the ethylenically unsaturated functional group is selected from allyl, vinyl, (meth)acrylate, (meth)acryloxy, (meth)acrylamido, and (meth)acryloyl.

In a preferred embodiment of the invention, curable component contains, in addition to the ethylenically unsaturated functional group and/or epoxy group, urethane groups, ether groups, ester groups, carbonate groups, and any combination thereof.

As curable component, the oligomer containing at least one radiation-curable functional group includes, for example, oligomers containing a core structure linked to the ethylenically unsaturated functional group, optionally via a linking group. The linking group can be an ether, ester, amide, urethane, carbonate, or carbonate group. In some instances, the linking group is part of the ethylenically unsaturated functional group, for instance an acryloxy or acrylamido group. The core group can be an alkyl (straight and branched chain alkyl groups), aryl (e.g., phenyl), polyether, polyester, siloxane, urethane, or other core structures and oligomers thereof. Suitable ethylenically unsaturated functional group may comprise groups containing carbon-carbon double bond, such as methacrylate groups, acrylate groups, vinyl ether groups, allyl ether groups, acrylamide groups, methacrylamide groups, acryloyl groups, methacryloyl groups, or a combination thereof. In some embodiments, suitable oligomers comprise mono- and/or polyfunctional acrylate, such as mono (meth)acrylate, di(meth)acrylate, tri(meth)acrylate, or higher, or combination thereof. Optionally, the oligomer may include a siloxane backbone in order to further improve cure, flexibility and/or additional properties.

In some embodiments, the oligomer containing at least one ethylenically unsaturated functional group can be selected from the following classes: urethane (i.e. an urethane-based oligomer containing ethylenically unsaturated functional group), polyether (i.e. an polyether-based oligomer containing ethylenically unsaturated functional group), polyester (i.e. an polyester-based oligomer containing ethylenically unsaturated functional group), polycarbonate (i.e. an polycarbonate-based oligomer containing ethylenically unsaturated functional group), polyestercarbonate (i.e. an polyestercarbonate-based oligomer containing ethylenically unsaturated functional group), epoxy (i.e. an epoxy-based oligomer containing ethylenically unsaturated functional group), silicone (i.e. a silicone-based oligomer containing ethylenically unsaturated functional group) or any combination thereof. Preferably, the oligomer containing at least one ethylenically unsaturated functional group can be selected from the following classes: a urethane-based oligomer, an epoxy-based oligomer, a polyester-based oligomer, a polyether-based oligomer, polyether urethane-based oligomer, polyester urethane-based oligomer or a silicone-based oligomer, as well as any combination thereof.

In a preferred embodiment of the invention, the oligomer containing at least one ethylenically unsaturated functional group comprises a urethane-based oligomer comprising urethane repeating units and one, two or more ethylenically unsaturated functional groups, for example those containing carbon-carbon unsaturated double bond, such as (meth)acrylate groups, (meth)acrylamide groups, allyl groups and vinyl groups. Preferably, the oligomer contains at least one urethane linkage (for example, one, two or more urethane linkages) within the backbone of the oligomer molecule and at least one acrylate and/or methacrylate functional groups (for example, one, two or more acrylate and/or methacrylate functional groups) pendent to the oligomer molecule. In some embodiments, aliphatic, cycloaliphatic, or mixed aliphatic and cycloaliphatic urethane repeating units are suitable. Urethanes are typically prepared by the condensation of a diisocyanate with a diol. Aliphatic urethanes having at least two urethane moieties per repeating unit are useful. In addition, the diisocyanate and diol used to prepare the urethane comprise divalent aliphatic groups that may be the same or different.

In one embodiment, the oligomer containing at least one ethylenically unsaturated functional group comprises polyester urethane-based oligomer or polyether urethane-based oligomer containing at least one ethylenically unsaturated functional group. The ethylenically unsaturated functional group can be those containing carbon-carbon unsaturated double bond, such as acrylate groups, methacrylate groups, vinyl groups, allyl groups, acrylamide groups, methacrylamide groups, acryloyl groups, methacryloyl groups etc., preferably acrylate groups and methacrylate groups.

Suitable urethane-based oligomers are known in the art and may be readily synthesized by a number of different procedures. For example, a polyfunctional alcohol may be reacted with a polyisocyanate (preferably, a stoichiometric excess of polyisocyanate) to form an NCO-terminated pre-oligomer, which is thereafter reacted with a hydroxy-functional ethylenically unsaturated monomer, such as hydroxy-functional (meth)acrylate. The polyfunctional alcohol may be any compound containing two or more OH groups per molecule and may be a monomeric polyol (e.g., a glycol), a polyester polyol, a polyether polyol or the like. The urethane-based oligomer in one embodiment of the invention is an aliphatic urethane-based oligomer containing (meth)acrylate functional group.

Suitable polyether or polyester urethane-based oligomers include the reaction product of an aliphatic or aromatic polyether or polyester polyol with an aliphatic or aromatic polyisocyanate that is functionalized with a monomer containing the ethylenically unsaturated functional group, such as (meth)acrylate group. In a preferred embodiment, the polyether and polyester are aliphatic polyether and polyester, respectively. In a preferred embodiment, the polyether and polyester urethane-based oligomers are aliphatic polyether and polyester urethane-based oligomers and comprise (meth)acrylate group.

In one embodiment, the viscosity of the oligomer containing at least one ethylenically unsaturated functional group at 25° C. can be in the range from 200 to 100000 cP, for example 200 cP, 300 cP, 400 cP, 600 cP, 800 cP, 1000 cP, 1500 cP, 2000 cP, 3000 cP, 4000 cP, 5000 cP, 6000 cP, 7000 cP, 8000 cP, 10000 cP, 20000 cP, 30000 cP, 40000 cP, 50000 cP, 60000 cP, 70000 cP, 80000 cP, 90000 cP, 95000 cP, preferably 300 to 60000 cP, for example 400 to 15000 cP, or 500 cP to 60000 cP, as measured according to DIN EN ISO 3219.

The monomer can lower the viscosity of the composition. The monomer can be monofunctional or multifunctional (such as difunctional, trifunctional, or tetrafunctional). In one embodiment, the monomer can be selected from the group consisting of (meth)acrylate monomers, (meth)acrylamide monomers, vinylaromatics having up to 20 carbon atoms, vinyl esters of carboxylic acids having up to 20 carbon atoms, vinyl ethers, α,β-unsaturated carboxylic acids having 3 to 8 carbon atoms and their anhydrides, and vinyl substituted heterocycles,

In the context of the present disclosure, term “(meth)acrylate monomer” means a monomer comprises a (meth)acrylate moiety. The structure of the (meth)acrylate moiety is as follows:

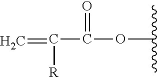

wherein R is H or methyl.

The (meth)acrylate monomer can be monofunctional or multifunctional (such as difunctional, trifunctional) (meth)acrylate monomer. Exemplary (meth)acrylate monomer can include C₁ to C₂₀ alkyl (meth)acrylate, C₁ to C₁₀ hydroxyalkyl (meth)acrylate, C₃ to C₁₀ cycloalkyl (meth)acrylate, urethane acrylate, 2-(2-ethoxy)ethyl acrylate, tetrahydrofurfuryl (meth)acrylate, 2-phenoxyethylacrylate, dicyclopentenyloxyethyl (meth)acrylate, dicyclopentadienyl (meth)acrylate, caprolactone (meth)acrylate, morpholine (meth)acrylate, ethoxylated nonyl phenol (meth)acrylate, (5-ethyl-1,3-dioxan-5-yl) methyl acrylate, phenyl (meth)acrylate, benzyl (meth)acrylate, phenethyl (meth)acrylate, dicyclopentanyl (meth)acrylate, 3,3,5-trimethylcyclohexyl (meth)acrylate and dicyclopentenyl (meth)acrylate.

Specific examples of C₁ to C₂₀ alkyl (meth)acrylate can include methyl (meth)acrylate, ethyl (meth)acrylate, isopropyl (meth)acrylate, n-propyl (meth)acrylate, n-butyl (meth)acrylate, isobutyl (meth)acrylate, tert-butyl (meth)acrylate, sec-butyl (meth)acrylate, pentyl (meth)acrylate, n-hexyl (meth)acrylate, octyl (meth)acrylate, isooctyl (meth)acrylate, 2-ethylhexyl (meth)acrylate, decyl (meth)acrylate, isodecyl (meth)acrylate, n-lauryl (meth)acrylate, n-tridecyl (meth)acrylate, n-cetyl (meth)acrylate, n-stearyl (meth)acrylate, isomyristyl (meth)acrylate, stearyl (meth)acrylate, and isostearyl (meth)acrylate (ISTA). C₆ to C₁₈ alkyl (meth)acrylate, especially C₆ to C₁₆ alkyl (meth)acrylate or C₆ to C₁₂ alkyl (meth)acrylate is preferred.

Specific examples of C₁ to C₁₀ hydroxyalkyl (meth)acrylate, such as C₂ to C₈ hydroxyalkyl (meth)acrylate can include 2-hydroxyethyl (meth)acrylate, 2-hydroxypropyl (meth)acrylate, 3-hydroxypropyl (meth)acrylate, 2-hydroxybutyl (meth)acrylate, 3-hydroxybutyl (meth)acrylate, 4-hydroxybutyl (meth)acrylate, 6-hydroxyhexyl (meth)acrylate, or 3-hydroxy-2-ethylhexyl (meth)acrylate etc.

Specific examples of C₃ to C₁₀ cycloalkyl (meth)acrylate can include isobornyl acrylate, isobornyl methacrylate, cyclohexyl acrylate or cyclohexyl methacrylate.

Examples of the multifunctional (meth)acrylate monomer can include (meth)acrylic esters and especially acrylic esters of polyfunctional alcohols, particularly those which other than the hydroxyl groups comprise no further functional groups or, if they comprise any at all, comprise ether groups. Examples of such alcohols are, e.g., difunctional alcohols, such as ethylene glycol, propylene glycol, and their counterparts with higher degrees of condensation, for example such as diethylene glycol, triethylene glycol, dipropylene glycol, tripropylene glycol etc., 1,2-, 1,3- or 1,4-butanediol, 1,5-pentanediol, 1,6-hexanediol, 3-methyl-1,5-pentanediol, neopentyl glycol, alkoxylated phenolic compounds, such as ethoxylated and/or propoxylated bisphenols, 1,2-, 1,3- or 1,4-cyclohexanedimethanol, alcohols with a functionality of three or higher, such as glycerol, trimethylolpropane, butanetiiol, trimethylolethane, pentaerythritol, ditrimethylolpropane, dipentaerythritol, sorbitol, mannitol, and the corresponding alkoxylated, especially ethoxylated and/or propoxylated, alcohols. For the alkoxylated phenolic compounds, the degree of alkoxylation is preferably from 2 to 40, from 2 to 30 or more preferred from 2 to 20, for example from 2 to 6, or from 8 to 20.

In the context of the present disclosure, term “(meth)acrylamide monomer” means a monomer comprises a (meth)acrylamide moiety. The structure of the (meth)acrylamide moiety is as follows: CH₂═CR¹—CO—N, wherein R¹ is hydrogen or methyl. Specific example of (meth)acrylamide monomer can include acryloylmorpholine, methacryloylmorpholine, N-(hydroxymethyl)acrylamide, N-hydroxyethyl acrylamide, N-isopropylacrylamide, N-isopropylmethacrylamide, N-tert-butylacrylamide, N,N′-methylenebisacrylamide, N-(isobutoxymethyl)acrylamide, N-(butoxymethyl)acrylamide, N-[3-(dimethylamino)propyl]methacrylamide, N,N-dimethylacrylamide, N,N-diethylacrylamide, N-(hydroxymethyl)methacrylamide, N-hydroxyethyl methacrylamide, N-isopropylmethacrylamide, N-isopropylmethacrylamide, N-tert-butylmethacrylamide, N,N′-methylenebismethacrylamide, N-(isobutoxymethyl)methacrylamide, N-(butoxymethyl)methacrylamide, N-[3-(dimethylamino)propyl]methacrylamide, N,N-dimethylmethacrylamide and N,N-diethylmethacrylamide. The (meth)acrylamide monomer can be used alone or in combination.

Examples of vinylaromatics having up to 20 carbon atoms can include, such as styrene and C₁-C₄-alkyl substituted styrene, such as vinyltoluene, p-tert-butylstyrene and α-methyl styrene.

Examples of vinyl esters of carboxylic acids having up to 20 carbon atoms (for example 2 to 20 or 8 to 18 carbon atoms) can include vinyl laurate, vinyl stearate, vinyl propionate, and vinyl acetate.

Examples of vinyl ethers are ethyl vinyl ether, propyl vinyl ether, isobutyl vinyl ether, cyclohexyl vinyl ether, 2-ethylhexyl vinyl ether, butyl vinyl ether, ethylene glycol monovinyl ether, diethyleneglycol divinyl ether, butane diol divinyl ether, hexane diol divinyl ether, cyclohexane dimethanol monovinyl ether and the like.

Example of α,β-unsaturated carboxylic acids having 3 to 8 carbon atoms can be acrylic acid or methacrylic acid.

Examples of vinyl substituted heterocycles can include monovinyl substituted heterocycles, wherein the heterocycle is a 5- to 8-membered ring containing 2 to 7 carbon atoms, and 1 to 4 (preferably 1 or 2) heteroatoms selected from N, O and S, such as vinylpyridines, N-vinylpyrrolidone, N-vinylmorpholin-2-one, N-vinyl caprolactam and 1-vinylimidazole, vinyl alkyl oxazolidinone such as vinyl methyl oxazolidinone.

Preferred monomers are (meth)acrylate monomer, (meth)acrylamide monomer, vinylaromatics having up to 20 carbon atoms, and vinyl substituted heterocycles.

In a preferred embodiment, the curable component comprises both the oligomer and the monomer containing at least one ethylenically unsaturated functional group. The weight ratio of the oligomer to the monomer can be in the range from 10:1 to 1:25, preferably from 8:1 to 1:20, or from 5:1 to 1:15, or from 3:1 to 1:10, for example 2:1, 1:1, 1:2, 1:3, 1:5, 1:8 or 1:9.

In an embodiment, the first and second compositions comprise as the curable component:
at least one oligomer containing at least one radiation-curable functional group, and
at least one monomer containing at least one radiation-curable functional group.

In an embodiment, the first and second compositions comprise as the curable component:
at least one oligomer containing at least one radiation-curable functional group, and at least one monofunctional monomer.

In an embodiment, the first and second compositions comprise as the curable component:
at least one oligomer containing at least one ethylenically unsaturated functional group, selected from the following classes: urethane, polyether, polyester, polycarbonate, polyestercarbonate, epoxy, silicone or any combination thereof; and
at least one monomer containing at least one radiation-curable functional group.

In an embodiment, the first and second compositions comprise as the curable component:
at least one oligomer containing at least one ethylenically unsaturated functional group, selected from the following classes: an urethane-based oligomer, an epoxy-based oligomer, a polyester-based oligomer, a polyether-based oligomer, urethane acrylate-based oligomer, polyether urethane-based oligomer, polyester urethane-based oligomer or a silicone-based oligomer, as well as any combination thereof; and
at least one monomer containing at least one radiation-curable functional group.

In an embodiment, the first and second compositions comprise as the curable component:
at least one oligomer containing at least one ethylenically unsaturated functional group, selected from the following classes: an urethane-based oligomer, an epoxy-based oligomer, a polyester-based oligomer, a polyether-based oligomer, urethane acrylate-based oligomer, polyether urethane-based oligomer, polyester urethane-based oligomer or a silicone-based oligomer, as well as any combination thereof;
at least one multifunctional monomer; and
at least one monofunctional monomer.

In an embodiment, the first composition comprises as the curable component:
a urethane-based oligomer containing ethylenically unsaturated functional group, and
a (meth)acrylic esters of polyfunctional alcohols, and
at least one monofunctional monomer.

In an embodiment, the first composition comprises as the curable component:
a urethane-based oligomer containing (meth)acrylate group,
a (meth)acrylic esters of polyfunctional alcohols, wherein the polyfunctional alcohols is an alkoxylated phenolic compounds, preferably the degree of alkoxylation is from 2 to 40, and
at least one monofunctional monomer.

In an embodiment, the first composition comprises as the curable component:
a urethane-based oligomer containing methacrylate group,
a (meth)acrylic esters of polyfunctional alcohols, wherein the polyfunctional alcohols is an alkoxylated phenolic compounds, preferably the degree of alkoxylation is from 8 to 20, and
at least one monofunctional monomer.

In an embodiment, the second composition comprises as the curable component:
a polyether urethane-based oligomer containing ethylenically unsaturated functional group,
a (meth)acrylic esters of polyfunctional alcohols, and
at least one monofunctional monomer.

In an embodiment, the second composition comprises as the curable component:
a polyether urethane-based oligomer containing (meth)acrylate group,
a (meth)acrylic esters of polyfunctional alcohols, wherein the polyfunctional alcohols is an alkoxylated phenolic compounds, preferably the degree of alkoxylation is from 2 to 40, and
at least one monofunctional monomer.

In an embodiment, the second composition comprises as the curable component:
a polyether urethane-based oligomer containing acrylate group,
a (meth)acrylic esters of polyfunctional alcohols, wherein the polyfunctional alcohols is an alkoxylated phenolic compounds, preferably the degree of alkoxylation is from 2 to 6, and
at least one monofunctional monomer.

### Photoinitiators

The first and the second compositions of the present invention can comprise at least one photoinitiator. For example, photoinitiator may include at least one free radical photoinitiator and/or at least one ionic photoinitiator, and preferably at least one (for example one or two) free radical photoinitiator. It is possible to use all photoinitiators known in the art for use in compositions for 3D-printing, e.g., it is possible to use photoinitiators that are known in the art suitable for SLA, DLP or PPJ processes.

Exemplary photoinitiators may include benzophenone, acetophenone, chlorinated acetophenone, dialkoxyacetophenones, dialkylhydroxyacetophenones, dialkylhydroxyacetophenone esters, benzoin and derivatives (such as benzoin acetate, benzoin alkyl ethers), dimethoxybenzion, dibenzylketone, benzoylcyclohexanol and other aromatic ketones, acyloxime esters, acylphosphine oxides, acylphosphonates, ketosulfides, dibenzoyldisulphides, diphenyldithiocarbonates.

For example, the free radical photoinitiator may be chosen from those commonly used to initiate radical photopolymerization. Examples of free radical photoinitiators include Irgacure®369, Irgacure® TPO-L, benzoins, e.g., benzoin, benzoin ethers such as benzoin methyl ether, benzoin ethyl ether, benzoin isopropyl ether, benzoin phenyl ether, and benzoin acetate; acetophenones, e.g., acetophenone, 2,2-dimethoxyacetophenone, 2,2-dimethoxy-2-phenylacetophenone and 1,1-dichloroacetophenone; benzyl ketals, e.g., benzyl dimethylketal and benzyl diethyl ketal; anthraquinones, e.g., 2-methylanthraquinone, 2-ethylanthraquinone, 2-tertbutylanthraquinone, 1-chloroanthraquinone and 2-amylanthraquinone; triphenylphosphine; benzoylphosphine oxides, e.g., 2,4,6-trimethylbenzoy-diphenylphosphine oxide (Lucirin TPO); ethyl-2,4,6-trimethylbenzoylphenylphosphinate; bisacylphosphine oxides; benzophenones, e.g., benzophenone and 4,4′-bis(N,N′-dimethylamino)benzophenone; thioxanthones and xanthones; acridine derivatives; phenazine derivatives; quinoxaline derivatives; 1-phenyl-1,2-propanedione 2-O-benzoyl oxime; 4-(2-hydroxyethoxy)phenyl-(2-propyl)ketone (Irgacure®2959); 2-methyl-1-[4-(methylthio)phenyl]-2-(4-morpholinyl)-1-propanone; 1-aminophenyl ketones or 1-hydroxy phenyl ketones, e.g., 1-hydroxycyclohexyl phenyl ketone, 2-hydroxyisopropyl phenyl ketone, phenyl 1-hydroxyisopropyl ketone, and 4-isopropylphenyl 1-hydroxyisopropyl ketone, and combinations thereof.

Specific examples of photoinitiators can include 1-hydroxycyclohexyl phenylketone, 2-methyl-1-[4-(methylthio)phenyl]-2-morpholinopropan-1-one, 2-benzyl-2-N,N-dimethylamino-1-(4-morpholinophenyl)-1-butanone, combination of 1-hydroxycyclohexyl phenyl ketone and benzophenone, 2,2-dimethoxy-2-phenyl acetophenone, bis(2,6-dimethoxybenzoy 1-(2,4,4-trimethylpentyl)phosphine oxide, 2-hydroxy-2-methyl-1-phenyl-propan-1-one, bis(2,4,6-trimethyl benzoyl) phenyl phosphine oxide, 2-hydroxy-2-methyl-1-phenyl-1-propane, 2,4,6-trimethylbenzoyldiphenyl-phosphine oxide, 2-hydroxy-2-methyl-1-phenyl-propan-1-one, 2,4,6-trimethylbenzoyldiphenylphosphinate and 2,4,6-trimethylbenzoyldiphenyl-phosphine oxide and also any combination thereof.

The amount of the photoinitiator can be in the range from 0.1 to 10% by weight, for example 0.2% by weight, 0.5% by weight, 0.8% by weight, 1% by weight, 2% by weight, 3% by weight, 5% by weight, 8% by weight, or 10% by weight, preferably from 0.1 to 5% by weight or 0.1 to 3% by weight, based on the total weight of the composition of the present invention.

### Additional Additives

For practical applications, optionally, the compositions of the present invention may further comprise additional additives, such as unreactive diluent and/or auxiliary agent, and the like.

Suitable unreactive diluents for the present invention comprise for example (bi)cycloaliphatics such as cyclohexane and its alkylated derivatives, and also decahydronaphthalene, cyclic sulfoxides such as sulfolane, nitrogen heterocycles such as pyridine, pyrimidine, quinoline, isoquinoline, quinaldine and N-methylpyrrolidone, and also carboxamides such as N,N-dimethylformamide and N,N-dimethylacetamide.

As auxiliary agents, mention may be made by way of preferred example of surfactant, flame retardants, nucleating agents, lubricant, dyes, pigments, catalyst, UV absorbers and stabilizers, e.g., against oxidation, hydrolysis, light, heat or discoloration, inorganic and/or organic fillers, reinforcing materials and plasticizers. As hydrolysis inhibitors, preference is given to oligomeric and/or polymeric aliphatic or aromatic carbodiimides. To stabilize the cured material of the invention against aging and damaging environmental influences, stabilizers are added to system in preferred embodiments.

Surfactants are surface active compounds, such as anionic, cationic, nonionic and amphoteric surfactants, and mixtures thereof. Such surfactants can be used for example as dispersant, solubilizer, and the like. Examples of surfactants are listed in McCutcheon's, Vol. 1: Emulsifiers & Detergents, McCutcheon's Directories, Glen Rock, USA, 2008 (International Ed. or North American Ed.).

If the composition of the invention is exposed to thermo-oxidative damage during use, in preferred embodiments, antioxidants are added. Preference is given to phenolic antioxidants. Phenolic antioxidants such as Irganox® 1010 from BASF SE are given in Plastics Additive Handbook, 5th edition, H. Zweifel, ed., Hanser Publishers, Munich, 2001, pages 98-107, page 116 and page 121.

If the composition of the invention is exposed to UV light, it is preferably additionally stabilized with a UV absorber. UV absorbers are generally known as molecules which absorb high-energy UV light and dissipate energy. Customary UV absorbers which are employed in industry belong, for example, to the group of cinnamic esters, diphenylcyan acrylates, formamidines, benzylidenemalonates, diarylbutadienes, triazines and benzotriazoles. Examples of commercial UV absorbers may be found in Plastics Additive Handbook, 5th edition, H. Zweifel, ed, Hanser Publishers, Munich, 2001, pages 116-122.

Further details regarding the abovementioned auxiliary agents may be found in the specialist literature, e.g., in Plastics Additive Handbook, 5th edition, H. Zweifel, ed, Hanser Publishers, Munich, 2001.

Plasticizers can be used to lower the glass transition temperature (Tg) of the polymer. Plasticizers work by being embedded between the chains of polymers, spacing them apart (increasing the “free volume”), and thus lowering the glass transition temperature of the polymer and making it softer.

When present, the amount of the additional additive(s) in the composition of the present invention may be in the range from 0 to 60% by weight, for example 5% by weight, 10% by weight, 15% by weight, 20% by weight, 25% by weight, 30% by weight, 35% by weight, 40% by weight, 50% by weight, 60% by weight, preferably from 0 to 50% by weight, or from 0 to 30% by weight, based on the total weight of the composition of the present invention.

The composition of the present invention can be prepared by mixing the components of the composition.

According to an embodiment of the invention, the mixing can be carried out at room temperature or elevated temperature (for example from 40 to 60° C.) with stirring. There is no particular restriction on the time of mixing and rate of stirring, as long as all components are uniformly mixed together. In a specific embodiment, the mixing can be carried out at 1000 to 3000 RPM, preferably 1500 to 2500 RPM for 5 to 60 min, more preferably 6 to 30 min. After stirring, the mixture can be filtrated. In this regard, a filter paper or capsule filters can be used.

### Building the Core and Shell and 3D Object

According to the present invention, the core of said 3D model is built from at least one first composition and the shell of said 3D model is built from at least one second composition according to the data generated, wherein the core is built by dispensing the at least one first composition from a first dispenser.

In an embodiment, the shell is built by dispensing the at least one second composition from a second dispenser, by dip coating the at least one second composition and/or by spin coating the at least one second composition.

According to the present invention, the dispensing can comprise dispensing via ink jet nozzles, dispensing via extrusion or dispensing via spray coating.

In a preferred embodiment, the core is built by dispensing the at least one first composition from the first dispenser via ink jet nozzles, and the shell is built by dispensing the at least one second composition from the second dispenser via ink jet nozzles.

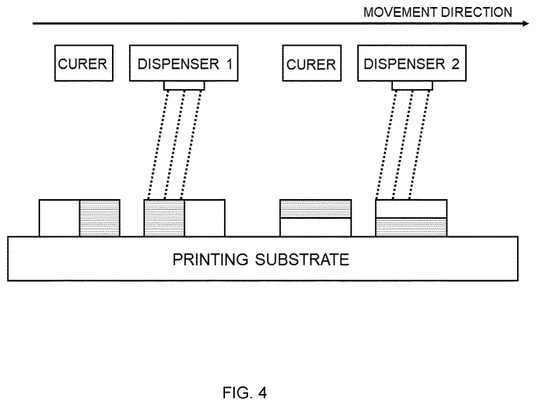

The 3D object of the present invention may be built using a 3D printing system. A 3D printing system is shown in FIG. 4. The 3D printing system includes two dispensers (1, 2), containing the first or second composition.

The dispenser may have a plurality of inkjet nozzles, through which the first and second compositions are jetted. For example, the first composition is jetted by dispenser 1 and the second composition is jetted by dispenser 2.

The 3D printing system can further include computer aided design (CAD) system and curers.

The 3D object is built in layers, the depth of each layer typically being controllable by selectively adjusting the output from each of the inkjet nozzles.

According to a preferred embodiment, the core and/or shell further comprises complex structure such as 2D-3D structure which exhibits isotropic properties, anisotropic properties, and a combination thereof.

The 2D-3D structure can be selected from structures used in conventional composite materials including honeycomb, stack, filaments, chessboard, waved-lines, spherical, cylindrical, Kelvin structure and weaved structures; the 2D-3D structure can also be selected from structures possessing negative Poisson ratios, including auxetic structures.

### Solidifying

According to the present invention, the solidifying in step (C) is carried out by heat, solvent evaporation, radiation such as UV radiation, electron beam and microwave, or any combination thereof. Preferably, the solidifying in step (C) is carried out by UV radiation or heat, or combination thereof.

In a specific embodiment, the wavelength of the radiation light can be in the range from 350 to 480 nm, for example 355, 360, 365, 385, 395, 405, 420, 440, 460 or 480 nm.

In one embodiment, step (B) and step (C) can be carried out as follows:
(I) forming layers of the first and second composition;
(II) applying radiation to cure at least a portion of the layers of the first and second composition to form cured layers;
(III) introducing new layers of the first and second compositions onto the cured layer;
(IV) applying radiation to the new layer of the first and second compositions to form new cured layers; and
(V) repeating steps (III) and (IV) until the 3D object is manufactured,
wherein step (I) and step (Ill) are carried out according to the data generated in step (A).

According to the invention, the curing time in step (II) or (IV) may be determined respectively by a skilled person according to practical application. For example, the curing time for each layer may be from 0.5 to 15 s, such as from 1 to 10 s.

In one embodiment, the process further comprises a step of post-curing the 3D object obtained in step (V) as a whole to form a final 3D object. The post-curing can be carried out by UV radiation, thermal treatment or combination thereof.

Usually, the temperature in the thermal treatment is in the range from 40 to 160° C., preferably 50 to 140° C. or 50 to 100° C. According to the invention, the post-curing time can be in the range from 15 min to 500 min, for example 15 min, 20 min 60 min, 120 min, 180 min, 250 min, 300 min, 400 min, preferably from 60 min to 250 min.

A further aspect of the present disclosure relates to a 3D object obtained by the process of the present invention.

According to the present invention, the multi-phase composite 3D object according to the present invention has improved mechanical properties, especially impact strength and elongation at break whereas modulus and tensile strength still remain high, comparing with the comparative 3D object having the same size without the shell.

As used herein, the comparative 3D object having the same size without the shell means a 3D object wherein the shell of the multi-phase composite 3D object according to the present invention is also formed from the same material of the core, i.e. the core extends to the full size of the multi-phase composite 3D object according to the present invention. Specific examples can refer to example 1 or example 11 of the present application.

In an embodiment, the unnotched impact strength of the multi-phase composite 3D object according to the present invention is at least 120%, preferably at least 140% or at least 160% of the unnotched impact strength of the comparative 3D object having the same size without the shell.

In an embodiment, the notched impact strength of the multi-phase composite 3D object according to the present invention is at least 150%, preferably at least 200% or at least 250% of the notched impact strength of the comparative 3D object having the same size without the shell.

In an embodiment, the elongation at break of the multi-phase composite 3D object according to the present invention is at least 120%, preferably at least 130% or at least 140% of the elongation at break of the comparative 3D object having the same size without the shell.

In an embodiment, the Young's modulus of the multi-phase composite 3D object according to the present invention is at least 60%, preferably at least 65% or at least 70% of the Young's modulus of the comparative 3D object having the same size without the shell.

The 3D objects can include sole, outerwear, cloth, footwear, toy, mat, tire, hose, gloves and seals.

### EXAMPLES

### Materials and Abbreviation

Bomar BR-541S: Difunctional polyether urethane acrylate, Tg 44° C., viscosity is 3000 mPa·s at 60° C., manufactured by Dymax.
Bomar BR-952: Difunctional aliphatic urethane methacrylate, Tg 159° C., viscosity is 7200 mPa·s at 25° C., manufactured by Dymax.
Miramer M2100: Bisphenol A (EO)10 diacrylate, Tg−7° C., viscosity is 600-700 at 25° C., manufactured by Miwon.
Miramer M240: Bisphenol A (EO)4 diacrylate, Tg 42° C., viscosity is 900-1300 at 25° C., manufactured by Miwon.
ACMO: Acryloylmorpholine, viscosity is 12-14 mPa·s at 25° C., available from RAHN.
IBOA: Isobomyl acrylate, viscosity is 10 mPa·s at 25° C., available from IGM.
HBA: 2-Hydroxy butyl acrylate, viscosity is 10.7 mPa·s at 20° C., available from BASF.
TPO: Omnirad TPO (2,4,6-trimethylbenzoyldiphenylphosphine oxide), available from IGM.

### Methods

(1) Tensile test
Tensile tests were carried out according to ASTM D638 Type-1 with Zwick Z050 tensile equipment, wherein the parameters used include: Grip to grip separation at the start position: 115 mm; Pre-load: 0.1 MPa; Test speed: 5 mm/min.
(2) Izod notched impact strength (ASTM-D256-10) at room temperature;
(3) Izod unnotched impact strength (ASTM-D4812-11) at room temperature

### Printer

A Notion PPJ 3D printer equipped with 2 Xaar 1003GS12 printheads.

### Preparation of Composition A and Composition B

The curable composition A and composition B were prepared by adding all components in weight amounts as shown in Table 1 into a plastic vial and mixing by FlackTek DAC.1 VAC-P speed-mixer at 2000 RPM for 10 minutes at 50° C. to ensure all solids were dissolved, followed by filtration with filter papers/capsule filters with 1 μm pore size to obtain the liquid curable compositions.

TABLE 1
composition A and composition B

| Formulation | Composition A (g) | Composition B (g) |
|---|---|---|
| BR-541S | 10 | |
| BR-952 | | 10 |
| M2100 | 35 | |
| M240 | | 25 |
| ACMO | 20 | 20 |
| IBOA | 30 | 45 |
| HBA | 5 | |
| TPO | 2 | 2 |
| Sum | 102 | 102 |

### Examples 1 to 9—Effects of Shell Thickness on Izod Unnotched Impact Strength

CAD was used to find the shells of the specimens by identifying regions covering the areas of all surfaces on a 3D shape. For example, the Izod unnotched impact strength test specimens in examples 1 to 9 were prepared according to ASTM-D4812-11, where the specimens were cuboids with dimensions 63.5 mm×12.7 mm×3.17 mm, in which case the shell of such a specimen covered all surfaces and was a collection of 6 quadrilateral surfaces.

The specimens in examples 1 to 9 were prepared by printing composition A together with Composition B, wherein the tough shells were printed with composition A, while the cores were printed with Composition B. Examples 1 to 9 had varied shell thicknesses from 0 μm to 1260 μm as shown in table 2 below.

The details for preparing the specimens are as follows: specimens were directly prepared by 3D printing with 40% UV energy (around 800 mW/cm², wavelength 385 nm) and 250 mm/s printing speed using a Notion PPJ 3D printer. Printed specimens were UV post-cured for 20 minutes with a NextDent UV curing box (UV intensity 6 mW/cm², wavelength 405 nm), followed by being vacuum dried at 60° C. for 12 hours using a Binder VD53 oven.

The unnotched Impact strength of the specimens obtained in examples 1 to 9 were shown in FIG. 5 and table 2.

TABLE 2
Effects of shell thickness on Izod unnotched impact strength.

| Examples | Shell thickness (μm) | Unnotched Impact strength (J/m) |
|---|---|---|
| 1 (reference) | 0 | 363.92 |
| 2 | 70 | 619.65 |
| 3 | 140 | 695.69 |
| 4 | 210 | 717.80 |
| 5 | 280 | 725.22 |
| 6 | 350 | 728.25 |
| 7 | 420 | 735.23 |
| 8 | 630 | 736.91 |
| 9 | 1260 | 741.31 |

As can be concluded from examples 1 to 9 that the shell made with composition A significantly improved the unnotched impact strength.

### Example 10 to 12 and Example 13 (Comparative)—Effects of Shell on Mechanical Properties

CAD was used to find the shells of the specimens by identifying regions covering the areas of all flat or curved surfaces that make up the outside of a 3D shape.

For tensile test specimens prepared according to ASTM D638-Type 1, the shell covers all surfaces and comprises 4 flat quadrilateral surfaces and 2 curved surfaces.

For Izod notched impact strength test specimen prepared according to ASTM-D256-10, the shell covers all surfaces and comprises 9 flat surfaces.

For Izod unnotched impact strength test specimens prepared according to ASTM-D4812-11, where the specimens were cuboids with dimensions 63.5 mm×12.7 mm×3.17 mm, in which case the shell covers all surfaces and comprises 6 flat quadrilateral surfaces.

The specimen in example 10 (reference) was prepared by printing composition A. The specimen in example 11 (reference) was prepared by printing composition B.

The specimens in example 12 were prepared by printing composition A together with composition B, wherein the tough shell was printed with composition A, while the core was printed with composition B. The thickness of the tough shell was 630 μm. The weight ratio of composition A to composition B is 7.7:92.3 in the specimens for testing Young's modulus, Tensile strength and Elongation at break. To maintain the shell thickness of 630 μm, the weight ratio of composition A to composition B is 12:88 in the specimen for testing notched impact strength; and the weight ratio of composition A to composition B is 10:90 in the specimen for testing Unnotched impact strength.

The specimens in example 13 (comparative) were prepared by printing a mixture of composition A and composition B with the same ratios as those in example 12. The weight ratio of composition A to composition B is 7.7:92.3 in the specimens for testing Young's modulus, Tensile strength and Elongation at break. The weight ratio of composition A to composition B is 12:88 in the specimen for testing notched impact strength; and the weight ratio of composition A to composition B is 10:90 in the specimen for testing Unnotched impact strength. Example 12 and example 13 contain the same ratios of composition A and composition B, but different structures, i.e., the specimens in examples 12 have core-shell structure, while the specimens in example 13 do not have the core-shell structure.

The details for preparing the specimens are as follows: specimens were directly prepared by 3D printing with 40% UV energy (around 800 mW/cm²) and 250 mm/s printing speed using a Notion PPJ 3D printer; the printed specimens were UV post-cured for 20 minutes with a NextDent UV curing box, followed by being vacuum dried at 60° C. using a Binder VD53 oven.

The mechanical properties of the specimens obtained in examples 10, 11, 12 and 13 were shown table 3.

TABLE 3

| | | | | notched | Unnotched |
|---|---|---|---|---|---|
| | Young's | Tensile | Elongation | impact | impact |
| | Modulus | strength | at break | strength | strength |
| Examples | (MPa) | (MPa) | (%) | (J/m) | (J/m) |
| 10(reference) | 1261.42 | 26.69 | 54.90 | 85.80 | 1166.35 |
| 11(reference) | 2235.54 | 49.04 | 6.10 | 21.20 | 363.92 |
| 12 (core-shell) | 2031.42 | 45.04 | 9.33 | 61.90 | 736.91 |
| 13 (mixture in | 1964.6 | 48.9 | 8.8 | 21.6 | 402.38 |
| same ratios) | | | | | |
| (comparative) | | | | | |

As can be concluded from the results in Table 3 that a 630 μm shell made of composition A in example 12 significantly increased the impact strength of the specimen without losing much of other mechanical properties, comparing with the specimen obtained in example 11. However, the impact strength, especially the notched impact strength of the specimen was not improved much when a mixture of composition A and composition B with the same ratio was used as shown in example 13.

### Example 14 to 23—Core Further Comprises Complex Structures

CAD was used to find the shells of the specimens by identifying regions covering the areas of all flat or curved surfaces that make up the outside of a 3D shape. For tensile test specimens prepared according to ASTM D638-Type 1, the shell covers all surfaces and comprises 4 flat quadrilateral surfaces and 2 curved surfaces.

The tensile specimen in example 14 was prepared by printing composition B. The specimen in example 15 was prepared by printing composition A.

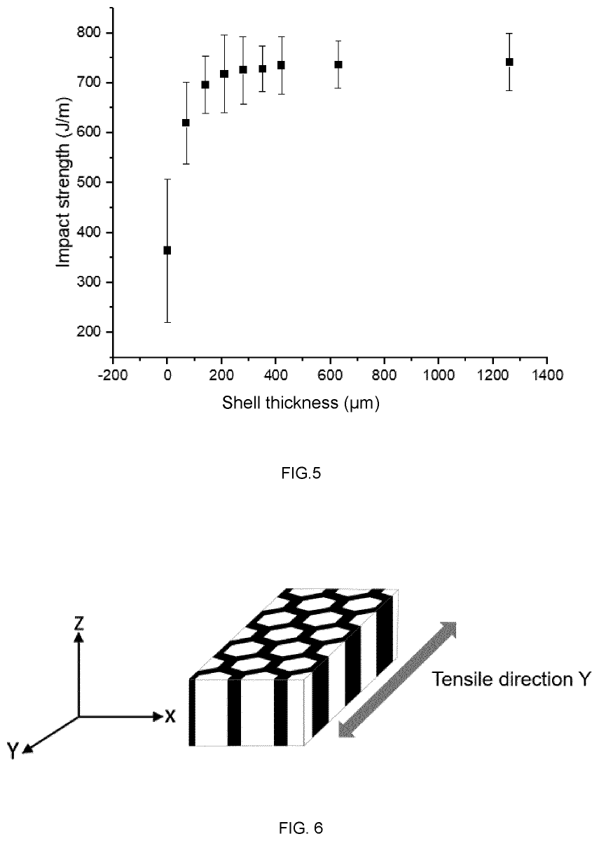

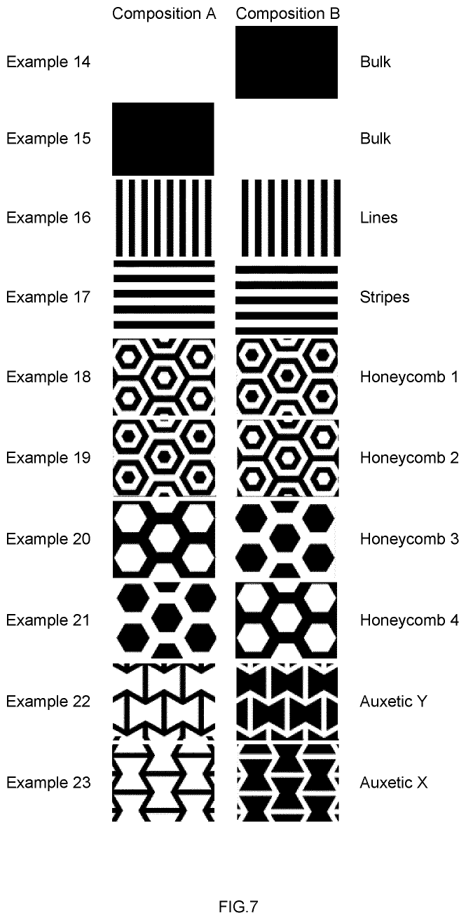

The tensile specimens in examples 16 to 23 were prepared by incorporating complex structures into tensile specimens via building cores of the specimens using different materials, as illustrated in FIG. 6, FIG. 7 and table 4.

The details for preparing the specimens are as follows: all specimens were directly prepared by 3D printing with 40% UV energy (around 800 mW/cm²) and 250 mm/s printing speed using a Notion PPJ 3D printer, the printed specimens were UV post-cured for 20 minutes with a NextDent UV curing box, followed by being vacuum dried at 60° C. using a Binder VD53 oven.

The tensile properties of the specimens obtained in examples 14 to 23 were shown table 4.

TABLE 4
Effects of complex structures on tensile
behaviors of the printed specimens

| | | Composition | Young's | Tensile | Elongation |
|---|---|---|---|---|---|
| | | B volume | modulus | strength | at break |
| | Structures | percentage (%)* | (MPa) | (MPa) | (%) |
| 14 | Bulk | 100.00 | 2235.54 | 49.04 | 6.10 |
| 15 | Bulk | 0.00 | 1261.42 | 26.69 | 54.90 |
| 16 | Lines | 50.00 | 1783.14 | 49.01 | 8.04 |
| 17 | Stripes | 50.00 | 1131.20 | 29.08 | 23.10 |
| 18 | Honeycomb 1 | 51.36 | 1770.12 | 32.56 | 12.96 |
| 19 | Honeycomb 2 | 48.64 | 1692.48 | 32.68 | 12.66 |
| 20 | Honeycomb 3 | 48.80 | 1707.73 | 33.54 | 31.63 |
| 21 | Honeycomb 4 | 51.20 | 1706.77 | 29.94 | 11.65 |
| 22 | Auxetic Y | 33.22 | 1616.96 | 31.75 | 25.00 |
| 23 | Auxetic X | 34.21 | 1514.95 | 30.51 | 11.05 |

*based on the whole specimen

As can be seen from the results in Table 4, complex structures within cores further altered the mechanical properties of the specimens, especially in elongation at break, allowing mechanical performances to be customized based on requirements.

### Example 24 to 26—Shell and Corn Further Comprises Complex Structures

CAD was used to find the shells of the specimens by identifying regions covering the areas of all flat or curved surfaces that make up the outside of a 3D shape.

For tensile test specimens prepared according to ASTM D638-Type 1, the shell covers all surfaces and comprises 4 flat quadrilateral surfaces and 2 curved surfaces.

For Izod unnotched impact strength test specimens were prepared according to ASTM-D4812-11, where the specimens were cuboids with dimensions 63.5 mm×12.7 mm×3.17 mm, in which case the shell covers all surfaces and comprises 6 flat quadrilateral surfaces.

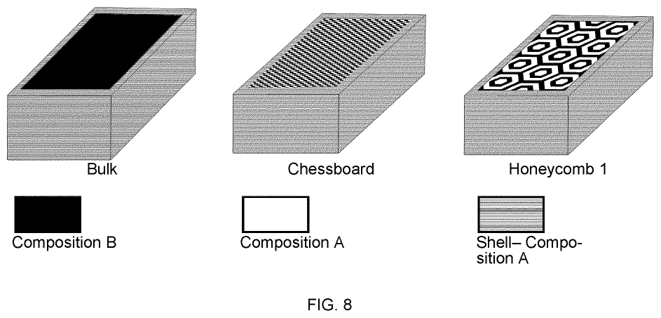

The specimens in examples 24 to 26 were prepared via building core and shell of the specimens using different materials, as illustrated in FIG. 8 and table 5. The thickness of the shell was 630 μm, which was formed from composition A. In example 24, the core was formed from composition B. In examples 25 and 26, the cores were formed from composition A and composition B.

The details for preparing the specimens are as follows: all specimens were directly prepared by 3D printing with 40% UV energy (around 800 mW/cm², wavelength 385 nm) and 250 mm/s printing speed using a Notion PPJ 3D printer; the printed specimens were UV post-cured for 20 minutes with a NextDent UV curing box (UV intensity 6 mW/cm², wavelength 405 nm), followed by being vacuum dried at 60° C. for 12 hours using a Binder VD53 oven.

TABLE 5
Effects of shell and complex structures within core
on mechanical properties of the printed specimens

| | | Composition | | | | Unnotched |
|---|---|---|---|---|---|---|
| | | B volume | Young's | Tensile | elongation | Impact |
| | Core | percentage | modulus | strength | at break | strength |
| example | structures | (%)* | (MPa) | (MPa) | (%) | (J/m) |
| 24 | Bulk | 90.96 | 2031.42 | 45.04 | 9.33 | 675.56 |
| 25 | Chessboard | 45.48 | 1643.64 | 36.09 | 31.18 | 645.76 |
| 26 | Honeycomb 1 | 47.18 | 1763.85 | 32.18 | 13.09 | 575.85 |

*based on the whole specimen
According to the results of examples 24 to 26, incorporation of shell and complex structures within core allowed the adjustment of the mechanical properties, especially impact strength and elongation at break.

1.-18. (canceled)

19. A process for the preparation of a multi-phase composite 3D object comprising a core and shell, which comprises:
(A) generating data of the core and shell of a 3D model of the 3D object;
(B) building the core of said 3D model from at least one first composition and building the shell of said 3D model from at least one second composition according to the data generated, wherein the core is built by dispensing the at least one first composition from a first dispenser; and
(C) solidifying the at least one first composition and the at least one second composition to obtain the multi-phase composite 3D object,
wherein the solidified material of the at least one first composition and the solidified material of the at least one second composition have different properties.

20. The process according to claim 19, wherein the data of the core and shell of a 3D model of the 3D object is generated from a computer aided design (CAD) system in step (A).

21. The process according to claim 19, wherein the thickness of the shell is at least 1 μm.

22. The process according to claim 19, wherein the thickness of the shell is in the range from 1 to 3000 μm.

23. The process according to claim 19, wherein the thickness of the shell is even or uneven.

24. The process according to claim 19, wherein the core comprises one or more layers.

25. The process according to claim 19, wherein the solidified material of the at least one first composition and the solidified material of the at least one second composition are different in at least one of following properties: mechanical properties, thermal properties, electronic properties, optical properties and chemical-resistance properties.

26. The process according to claim 25, wherein the mechanical properties comprise at least one of following properties: Young's modulus, tensile strength, elongation at break, tensile toughness, and impact strength.

27. The process according to claim 19, wherein the at least one first composition and the at least one second composition meet at least one of following conditions:
(i) the unnotched impact strength of the solidified material of the at least one second composition is at least 150% of the unnotched impact strength of the solidified material of the at least one first composition;
(ii) the notched impact strength of the solidified material of the at least one second composition is 150% of the notched impact strength of the solidified material of the at least one first composition;
(iii) the elongation at break of the solidified material of the at least one second composition is at least 150% of the elongation at break of the solidified material of the at least one first composition.

28. The process according to claim 19, wherein the at least one first composition and the at least one second composition meet at least one of following conditions:
(iv) the Young's modulus of the solidified material of the at least one first composition is at least 120% of the Young's modulus of the solidified material of the at least one second composition;
(v) the tensile strength of the solidified material of the at least one first composition is at least 120% of the tensile strength of the solidified material of the at least one second composition.

29. The process according to claim 19, wherein, the shell is built by dispensing the at least one second composition from a second dispenser, by dip coating the at least one second composition and/or by spin coating the at least one second composition.

30. The process according to claim 19, wherein the dispensing comprises dispensing via ink jet nozzles, dispensing via extrusion or dispensing via spray coating.

31. The process according to claim 19, wherein the core is built by dispensing the at least one first composition from a first dispenser via ink jet nozzles, and the shell is built by dispensing the at least one second composition from a second dispenser via ink jet nozzles.

32. The process according to claim 19, wherein the core and/or shell further comprises 2D-3D structure which exhibits isotropic properties, anisotropic properties, or a combination thereof.

33. The process according to claim 32, wherein the 2D-3D structure is selected from honeycomb, auxetic, stack and chessboard structure.

34. The process according to claim 19, wherein at least one of compositions comprises a curable component.

35. The process according to claim 19, wherein the solidifying in step (C) is carried out by heat, solvent evaporation, radiation, or any combination thereof.

36. A multi-phase composite 3D object obtained by the process according to claim 19.
